(19) United States
(12) Patent Application Publication
(10) Pub. No.: US 2024/0120293 A1
(43) Pub. Date: Apr. 11, 2024

(54) Method and Apparatus for Prevention, Cessation, Detection, and Monitoring of Cracks in Substrates

(71) Applicant: Chipletz, Inc., Spicewood, TX (US)

(72) Inventors: Michael Su, Austin, TX (US); Siddharth Ravichandran, Austin, TX (US); Michael Alfano, Austin, TX (US); Bryan Black, Austin, TX (US)

(73) Assignee: Chipletz, Inc., Spicewood, TX (US)

(21) Appl. No.: 18/378,235

(22) Filed: Oct. 10, 2023

Related U.S. Application Data
(60) Provisional application No. 63/414,778, filed on Oct. 10, 2022.

(51) Int. Cl. H01L 23/00; H01L 21/48; H01L 23/498

(52) U.S. Cl. CPC H01L 23/562; H01L 21/486; H01L 23/49822

(57) ABSTRACT

A semiconductor package substrate with embedded crack cessation structures and methods of forming the same is provided. Crack cessation structures include blind vias structures, through vias structures, and methods of forming the same are provided. Crack cessation structures may be formed by trenching of one or more structures, and deposition of metallic or insulative materials to form a crack cessation structures in the semiconductor package substrate core.

### CROSS-REFERENCE TO RELATED APPLICATIONS

This application is related to the following:
1. Provisional Application Ser. No. 63/414,778, filed 10 Oct. 2022 (“Parent Provisional”).

This application claims priority to the Parent Provisional, and hereby claims benefit of the filing date thereof pursuant to 37 C.F.R. § 1.78(a).

The subject matter of the Parent Provisional in its entirety is expressly incorporated herein by reference.

### FIELD OF THE INVENTION

Embodiments of the present invention are directed to semiconductor packaging and, more particularly, to improve performance of substrate materials by utilizing various crack prevention techniques, crack-stop techniques, and detecting substrate splitting and cracking.

### BACKGROUND

In general, in the descriptions that follow, the first occurrence of each special term of art that should be familiar to those skilled in the art of integrated circuits (“ICs”) and systems will be italicized. In addition, when a term that may be new or that may be used in a context that may be new, that term will be set forth in bold and at least one appropriate definition for that term will be provided. Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Integrated circuit (“IC”) packages may include multiple dies, passive components, and a package substrate. The package substrate may include one or more dielectric layers and a one or more of interconnects and/or interconnecting layers. The package substrate may be a laminated substrate. The interconnects may include traces, pads and/or vias. The dies may be coupled to the package substrate through solder balls and the like. The package substrate may be coupled to a printed circuit board (“PCB”) through solder balls and the like. An inductor may be mounted on the PCB. The inductor may be located externally to the IC package, and takes up a lot real estate on the PCB.

The rapidly growing demand for semiconductor packages like Ball Grid Arrays (BGA), Chip Scale Packages (CSP), and System-in-Package (SIP) has led to an equally strong demand for substrates that these packages employ. Substrates are parts that provide the package with mechanical base support and a form of electrical interface that allows electrical access to the device housed within the package. There are several types of package substrates, but the two major categories are rigid and tape substrates. As their names imply, these two categories differ with respect to their mechanical properties. Rigid substrates have a fixed shape and form, while tape substrates are thin and flexible. Early rigid substrates were mostly made of ceramic, but today organic substrates have become more widely deployed among various packages.

Rigid substrates that are composed of a stack of thin layers or laminates are called ‘laminate’ substrates. There are several different materials used for manufacturing laminate substrates. Two widely used materials for laminate substrates are FR4, a traditional epoxy-based laminate, and the more advanced and higher-performing resin-based BT-Epoxy, where BT stands for bismaleimide triazine.

Tape substrates are composed of high-strength and high-temperature polymer material such as polyimide. One major advantage of tape substrates is quite obvious: it is compliant enough to be subjected to motion while carrying the circuits built onto them, which is useful in ‘moving’ applications such as disk drives and printers. Tape substrates are also light-weight, less costly, and better than laminate substrates in achieving fine-line and microvia features, a fact that CSP's took advantage of in pursuit of fine-pitched wiring. The disadvantages of tape substrates include: 1) more difficult handling during processing; 2) warpage issues; and 3) large differences in coefficient of thermal expansion (CTE) with other materials such as solder masks.

Aside from serving as a base for Integrated Circuit (IC) packages, substrates are also used to route the chip's I/O system to the application board's interconnection features. Thus, substrates must somehow have within themselves metal conductors that can accomplish this routing function. These are usually in the form of traces etched from copper foil that's bonded to one or more laminates of the substrate. The copper layers of the substrate are commonly finished with a layer of immersion gold over a layer of electroless nickel. The nickel prevents copper-solder interdiffusion while the gold inhibits oxidation and enhances solderability.

A laminate substrate may have several layers with metal planes or traces that are interconnected to each other by through-hole plated vias, in much the same way as conventional PCB's. BT substrates often have an even number of routing layers. In a 4-layer substrate, for instance, the I/O routing planes are the ones at the top and bottom of the substrate, while the inner layers are used as a ground and power plane.

In recent years, glass has gained considerable interest for electronic components, due to its very attractive electrical, physical, and chemical properties, as well as its prospects for a relevant, cost-effective solution. As of today, the application scope of glass substrates in the semiconductor field is broad and highly diversified. Among the many various functionalities within IC and semiconductor devices, glass may be used as a substrate core or as a temporary carrier that can undergo many fabrication process steps such as etching, deposition of material, and photolithographic patterning.

Of course, these substrate core materials such as glass may be brittle material with inherent defects from the formation of the core itself or defects introduced from external forces. The substrate core defects can grow into large cracks that are highly destructive defects from energy gained from the additional stress or stress/strain build up. By way of example, some of the ways the destructive defects may occur are:
Accumulated tensile stresses, introduced through subsequent build up layers;
Handling: cutting, grinding, shock and vibration, testing, transportation, packaging, etc.;
Large temperature gradients in cooling across the x, y, and z dimensions; and
Long term reliability stress such as thermal cycling, high temperature stress test, etc.

These defects can grow into cracks in both substrate panels/strip/wafer and individual substrate level. The state-of-the-art technique for stopping these cracks is using crack stops, also known as die seal rings for a silicon device, which are formed using copper (Cu) redistribution layers (RDL) that only covers the RDL portion of the die only. There is no crack stop in the silicon portion of the die, as this application is the bulk region of the “die”.

Therefore, there is a need for a crack prevention apparatus and method for use with package substrates that should provide performance generally comparable to the best prior art techniques but more efficiently than known implementations of such prior art techniques. Likewise, there is a need for a crack cessation apparatus and method for use with package substrates that should provide performance generally comparable to the best prior art techniques but more efficiently than known implementations of such prior art techniques. And similarly, there is a need for a crack detection apparatus and method for use with package substrates that should provide performance generally comparable to the best prior art techniques but more efficiently than known implementations of such prior art techniques.

### BRIEF SUMMARY OF THE INVENTION

According to one embodiment, a semiconductor package substrate core comprising a substrate core material, at least one crack cessation structure formed within said substrate core material, said crack cessation structure being formed in said substrate core material to a first depth, and wherein said crack cessation structure comprises at least a selected one of one hole and one trench; said crack cessation structure being further characterized as being filled with a selected one of an insulative material and a metallic material.

According to a different embodiment, a method for manufacturing a semiconductor package substrate core, comprising forming a substrate core material, forming at least one crack cessation structure in said substrate core material, said crack cessation structure being formed in said substrate core material to a first depth, said crack cessation structure comprising at least a selected one of one hole and one trench, and filling the at least a selected one of one hole and one trench with a selected one of an insulative material and a metallic material.

According to a different embodiment, a semiconductor package substrate core comprising a substrate core material, and at least one crack cessation structure formed within said substrate core material, said crack cessation structure further comprising, a first hole formed in said substrate core material to a first depth, said hole being formed in a first surface of said substrate core material, and said hole being filled with a selected one of an insulative material and a metallic material, and a second hold formed in said substrate core material to a second depth, said hole being formed in a second surface of said substrate core material opposite said first surface, and said hole being filled with a selected one of an insulative material and a metallic material.

According to a different embodiment, an apparatus comprising a substrate, a first defect sensor structure comprising, a first plated-through hole disposed in said substrate having a first top terminal disposed on a first surface of said substrate, and a first bottom terminal disposed on a second surface of said substrate, a second plated-through hole disposed in said substrate having a top terminal disposed on said first surface of said substrate, and a second bottom terminal disposed on said second surface of said substrate, and a conductive connecting track coupled to said first bottom terminal and to said second bottom terminal, and said first defect sensor structure configured to receive a detection signal therethrough between the first top terminal and the second top terminal to detect a break in the conductive track between said first and second top terminals and thereby detect a defect in the substrate.

### BRIEF DESCRIPTION OF THE SEVERAL VIES OF THE DRAWINGS

Aspects of the present invention are best understood from the following description when read with the accompanying figures.

FIG. 1 illustrates, in diagrammatic form, an exemplary substrate core with a simple edge defect according to some embodiments;

FIG. 2 illustrates, in diagrammatic form, the exemplary substrate core of FIG. 1 with an initial build-up layer having been applied, according to some embodiments;

FIG. 3 illustrates, in diagrammatic form, the exemplary substrate core of FIG. 2 with additional build-up layer having been applied to initial build-up layer according to some embodiments;

FIG. 4 illustrates, in diagrammatic form, a crack retardation method, specifically, the method includes an exemplary sacrificial edge coating useful at a substrate panel level and/or a unit level according to some embodiments;

FIG. 5 illustrates, in diagrammatic form, another crack retardation method according to some embodiments;

FIG. 6 illustrates, in diagrammatic form, a crack prevention method according to some embodiments;

FIG. 7 illustrates, in diagrammatic form, an exemplary structure of applying build-up dielectric layer to a substrate core utilizing slits in the dicing lanes or street around each package unit to reduce tensile stress on each die;

FIG. 8 illustrates in diagrammatic form an exemplary form of a crack stop that may be used in various substrate regions according to some embodiments;

FIG. 9 illustrates, in diagrammatic form, one exemplary crack stop structure according to some embodiments;

FIG. 10 illustrates, in diagrammatic form, multiple exemplary crack stop structures according to several of the embodiments;

FIG. 11 illustrates, in diagrammatic form, multiple exemplary crack stop structures according to several of the embodiments;

FIG. 12 illustrates, in diagrammatic form, an exemplary crack stop structure in a linearly arrayed combination of the through vias in substrate material as well as an exemplary crack stop structure in a linearly arrayed combination of the trenched vias and irregular 3-D through via in substrate material, according to some embodiments;

FIG. 13 illustrates, in diagrammatic form, an exemplary crack stop structure in a staggered array combination of the through vias in substrate material as well as an exemplary crack stop structure in a staggered array combination of the trenched vias and irregular 3-D through via in substrate material, according to some embodiments;

FIG. 14 illustrates, in diagrammatic form, crack stop patterns that may be utilized at both a panel level as well as at a unit level according to some embodiments;

FIG. 15 illustrates, in diagrammatic form, additional crack stop patterns that may be utilized at both a panel level as well as at a unit level according to some embodiments;

FIG. 16 illustrates in diagrammatic form exemplary partial continuous trench crack-stop structures according to some embodiments;

FIG. 17 illustrates, in diagrammatic form, another exemplary crack-stop structure according to some embodiments;

FIG. 18 illustrates in diagrammatic form an exemplary reconstituted crack-stop wall according to some embodiments;

FIG. 19 illustrates, in diagrammatic form, an exemplary substrate core with a crack-stop structure having been placed therein according to some embodiments;

FIG. 20 illustrates a cross-sectional of a Z-plane crack-monitor structure that uses a daisy-chained crack-stop structure according to some embodiments; and

FIG. 21 illustrates, in diagrammatic form, a top view of a Z-plane crack-monitor structure that uses a daisy-chained crack-stop structure according to some embodiments.

### DETAILED DESCRIPTION

Crack displacement in semiconductor package substrates can occur through various modes, each with its unique characteristics and mechanisms. Understanding these modes is essential for assessing the reliability and performance of electronic devices. There are at least three modes of crack displacement: (a) Mode I: opening (or tensile) mode; (b) Mode II: sliding (or in-plane shearing) mode; and (c) Mode III: tearing (or anti-plane shearing) mode.

There may be many reasons for a crack to develop in a substrate. By way of example, one common reason in brittle substrate core may be related to the tensile stress at the edge of the substrate surface. Causes of this tensile stress at the edge of the substrate surface may include: (a) coefficient of thermal expansion (“CTE”) mismatch of the buildup dielectric layers; (b) shrinkage of the build-up dielectric layers during the curing process; and (c) large temperature gradients in the heating and cooling through the various processing steps.

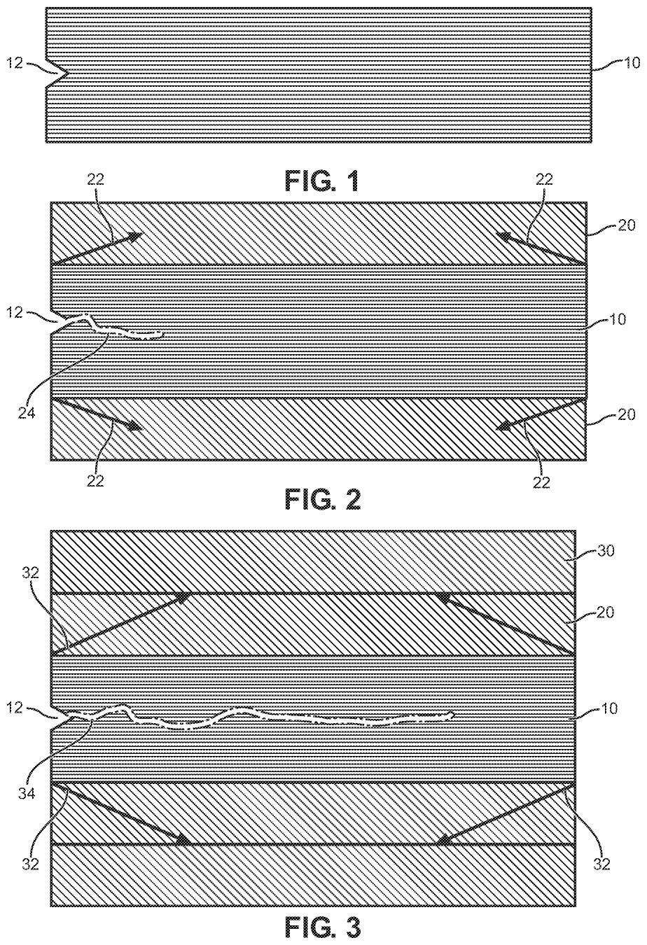

By way of example, the tensile stress turns inherent defects on the edge or even in the bulk of the substrate into tiny cracks. These tiny cracks may be the result of such actions as the sawing of the substrate or the formation of the core itself. These tiny cracks may then grow larger as more stress accumulates, ultimately resulting in the failure of the substrate to function as desired. Stress accumulates during the application of additional build-up layers. FIG. 1 illustrates, in diagrammatic form, an exemplary substrate core 10 with a simple edge defect 12 according to some embodiments. FIG. 2 illustrates, in diagrammatic form, the exemplary substrate core 10 of FIG. 1 with an initial build-up layer 20 having been applied, indicating initial tensile stresses 22 that are a result of the build-up layer 20 being applied, and a crack 24 in the substrate initiated as a result of the inherent tensile stresses 22. Each build-up layer 20 may be formed by way of two steps. The first step may include, by way of example, roll-lamination, vacuum-lamination, molding, spin-coating, spray-coating, etc. of a liquid or dry-film build-up of dielectric material. The second steps may include, by way of example, thermal cure, UV cure, or thermocompression cure of the dielectric material. The second step may cause the build-up material to harden or cross-link which may result in a physical shrinking of the buildup layer known as cure-shrinkage. The mismatches in CTE between the build-up material and the substrate core 10 along with the cure-shrinkage ultimately results in the tensile stresses 22 on the surface of the core as shown in FIG. 2. FIG. 3 illustrates, in diagrammatic form, the exemplary substrate core 10 of FIG. 2 with additional build-up layer 30 having been applied to initial build-up layer 20. This additional build-up layer 30 accumulates addition tensile stress 32. The accumulated tensile stress 32 results in the simple edge defect 12 transforming into a substantial crack propagation 34. Defects may be present anywhere in the substrate core 10, but defects at the corners typically may have the highest probability of initiating cracks next to a perimeter line of the substrate.

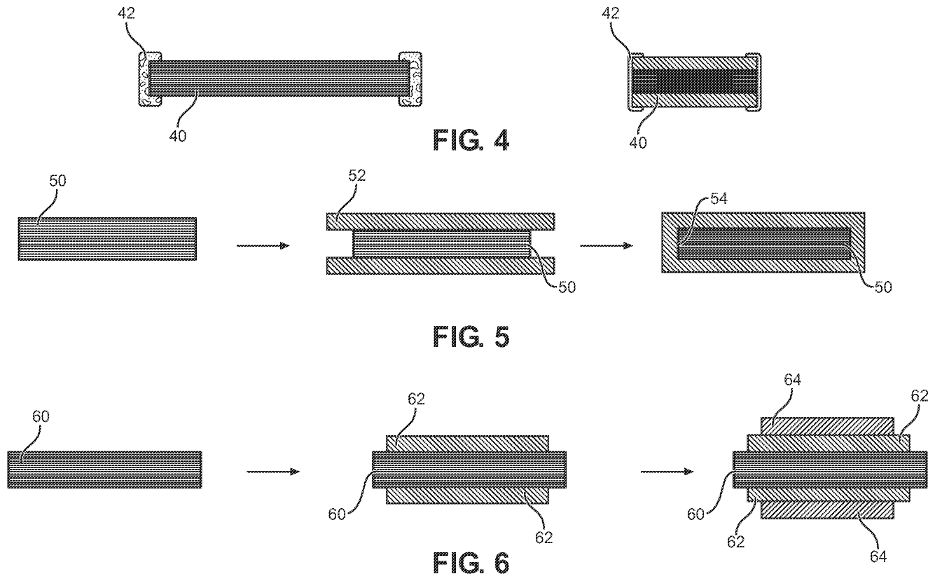

Crack retardation may be accomplished via a number of ways. One such exemplary crack retardation method may be to utilize chemical etching of the edges to remove or blunt sharp defects. By way of example, hydrofluoric acid (HF) may be applied to the edges of the substrate core to remove or blunt sharp defects. This could be applied to the substrate core prior to build-up processing, and/or after any core structuring steps such as cavity or through-hole formation, and/or post unit dicing after the fabrication of substrate build-up layers. The substrate core at any of these steps may be spray-etched, dip-etched, spin-etched, etc. with the etching agent. Another exemplary crack retardation method involves using edge coverings to counter tensile stress at the edges of the substrate core, and protect crack initiation due to handling of the substrate core. By way of example, the edge covering may be a polymeric or metallic covering. FIG. 4 illustrates, in diagrammatic form, a crack retardation method according to some embodiments. Specifically, the method includes an exemplary sacrificial edge coating useful at a substrate panel level and/or a unit level according to some embodiments. These methods may include single and/or multiple layers, those multiple layers may use different CTE to create compressive stress. A metallic edge coating 42 may be physically or chemically deposited on the substrate core 40 during processing. A metallic edge coating may also be plated during processing. A polymer edge 42 coating may be needle dispensed, spin coated, spray coated, etc. In either case, a patterning step may be employed to control the local application of the metallic edge or polymer edge coating. These edge coatings (or coverings) may be applied at the panel or wafer level or at the unit level after singulation. When applied at panel or wafer level, the edge coating may be temporary and could be removed by dicing or etching at any point.

FIG. 5 illustrates, in diagrammatic form, another crack retardation method according to some embodiments. This method includes using an exemplary laminate or molded dielectric 52 that is larger than the substrate core 50 thus allowing the dielectric material 52 to wrap around the substrate core 50, applying compressive stress at the edges 54, according to some embodiments. Such coatings reduce the number of free-edges that may turn into cracks, and may also reduce the surface energy of the substrate core when exposed to external crack aggressors such as moisture, physical contacts, etc. Each build-up layer may be formed in two steps. The first step involves deposition of the dielectric material 52 onto the substrate core 50 using, by way of example, roll-lamination, vacuum-lamination, molding, spin-coating, spray-coating, etc. of a liquid or dry-film build-up dielectric material. The second step involves flowing and curing the deposited dielectric material 52 using, by way of example, thermal cure, UV cure, or thermocompression cure of the dielectric material 52. During the cure step, the dielectric material 52 ‘flows’ before shrinking & hardening thus forming a wrap-around mold 56 over the core edge.

Crack prevention may also be accomplished by reducing the tensile stress at the edges of the substrate core by building the dielectric layers in a wedding cake like structure. FIG. 6 illustrates, in diagrammatic form, a crack prevention method according to some embodiments. The crack prevention method of FIG. 6 includes an exemplary structure demonstrating the building up of layers around the substrate core 60. In order to reduce the tensile stress at the edges of the substrate core 60, the dielectric material 62 is deposited and built up into the aforementioned wedding cake like structure 64. This wedding cake structure 64 is accomplished by recessing each subsequent layer from the previous layer, thus effectively tapering the stresses accumulated at the corners. Each layer of dielectric material 62 and RDL may be recessed from the previous layer, thus tapering the stress accumulated at the corners of the substrate core 60. The recess could be achieved by pre-patterning the buildup layer, or after build-up layer formation through chemical etching or laser ablation techniques.

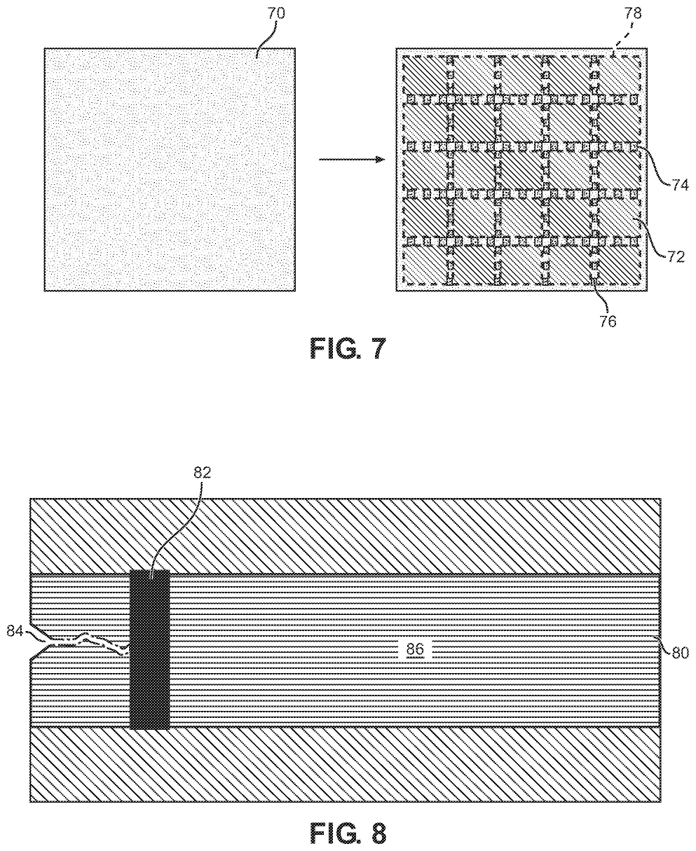

A similar reduction in tensile stress may be accomplished by utilizing cut-outs or slits in the dicing lanes and/or other unused area on a substrate core panel 70, as illustrated in FIG. 7. Prior to the dicing step, after build-up of dielectric layers 72 is performed, cut-outs or slits 74 are created in the dielectric layer. These slits 74 could also be sequentially recessed to form a wedding cake like structure similar to FIG. 6. FIG. 7 illustrates in diagrammatic form an exemplary structure of applying build-up dielectric layer to a substrate core utilizing slits in the dicing lanes or street 76 around each package unit 78 to reduce tensile stress on each die.

Once an edge defect turns into a crack, one of the goals is to arrest the crack from entering the active substrate region. One way to accomplish this goal may be to dissipate and/or blunt the energy of the crack. In some instances, the blunting or diverting of the energy of the propagating crack may be accomplished by angular interference, thus deflecting the energy, and causing the loss of crack energy. This energy diversion thus diverts the crack away from the active substrate region before the crack further propagates, i.e., arresting the crack propagation. FIG. 8 illustrates in diagrammatic form an exemplary form of a crack stop that may be used in various substrate regions according to some embodiments. The exemplary crack-stop 82 is placed within the substrate core 80, which thus can stop a crack 84 from entering the active substrate core region (86).

While a lot of work has been done on crack-stops on the silicon RDL layers, crack-stops in package substrate core are new. State of the art package substrates are plastic materials, and therefore not brittle, and hence not prone to cracking. However, brittle materials, e.g., glass, on the other hand, provide many advantages when used as package substrate, e.g., better dimensional stability, etc. but are prone to cracking in x-, y-, z- or a combination of many planes. Various crack stop structures may be used to arrest cracks in a substrate core according to some embodiments.

According to at least some embodiments, exemplary substrate crack stop structures that may be used in this context comprise:
a hole (circular or polygonal) or trench in the substrate core;
a hole (circular or polygonal) or trench in the substrate core that may be partially or fully plugged with an insulator;
a hole (circular or polygonal) or trench in the substrate core that may be partially or fully plated/plugged with a conductor;
a hole (circular or polygonal) or trench in the substrate core that may be partially or fully plugged with an insulator and a conductor;
any of the preceding may be connected to metal top and bottom side of substrate core; and
any of the preceding may be connected to the RDL layer crack stop at both top and bottom of the substrate core.

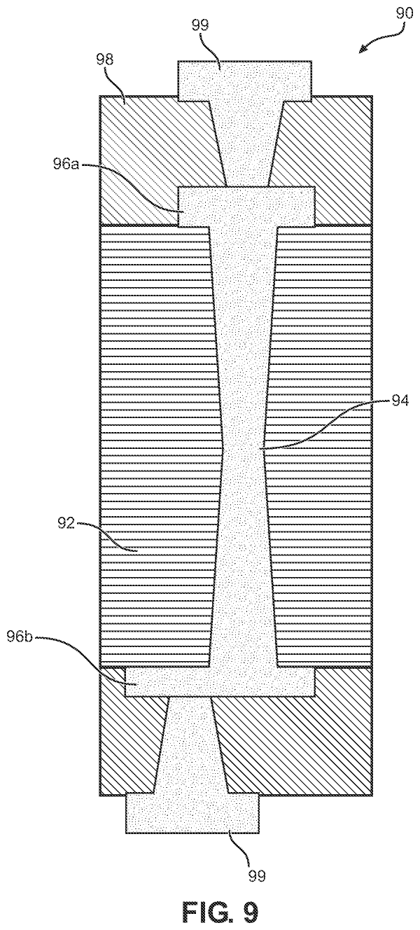

FIG. 9 illustrates, in diagrammatic form, one exemplary crack stop structure according to some embodiments. The exemplary crack stop structure 90 of FIG. 9 illustrates a package substrate core 92 with a hole bored through the substrate core and filled with a metal plug 94. The metal plug 94 may be connected to a metal top 96a and bottom side 96b of the substrate core. Crack stop structures in the build-up layers 98 connect by way of via connections 99 to the upper and lower RDL layers.

This structure may or may not be electrically connected to the package circuitry. Structures such as this may be used to stop cracks at a substrate panel level, a substrate strip level, at a substrate wafer level, or at the individual substrate unit level. In this disclosure, the term hole refers to individual 3D structures; the term trench refers to larger slits or cut-outs.

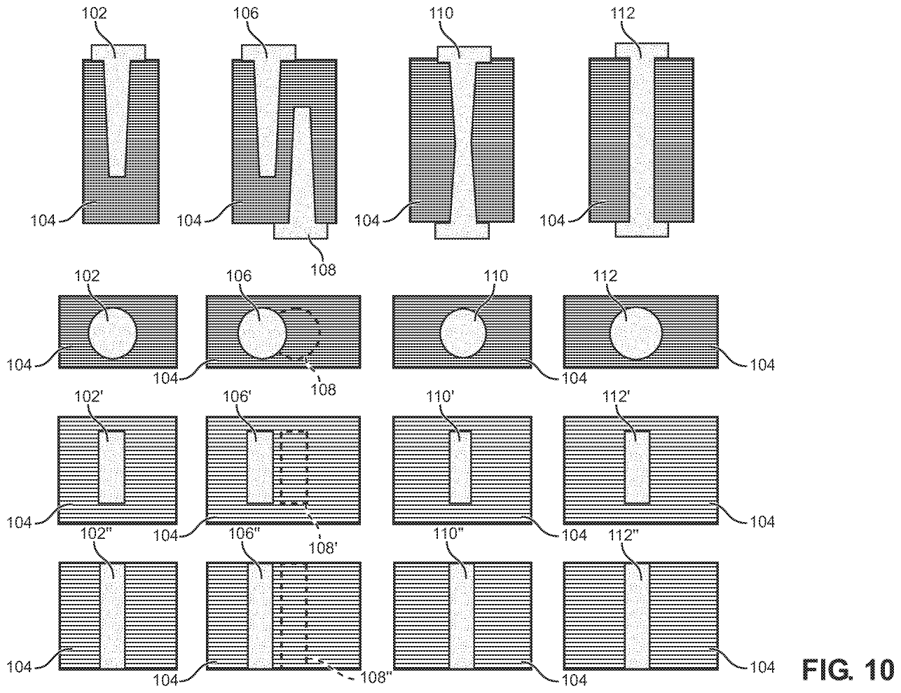

FIG. 10 illustrates, in diagrammatic form, multiple exemplary crack stop structures according to several of the embodiments. FIG. 10 illustrates the cross-section view of each of the exemplary crack stop structures along with the top view of each in three different forms: (i) a hole; (ii) a partial trench; and (iii) a continuous trench. As shown, FIG. 10 illustrates a single blind via 102 as a crack stop structure according to some embodiments. Single blind via 102 is created as a tapered bore hole, having a larger diameter at the top and a narrower diameter at its lower termination point approximately two-thirds through the substrate material 104. The tapered bore hole may be created by using any of the various methods for drilling fine holes in a substrate, including mechanical drilling, laser drilling, electric sputtering, and etching. Single blind via 102 is then filled with materials as discussed above, i.e., insulator material, conductor material, or a combination of both. Three separate top views of single blind via 102 are illustrated showing single blind via 102 as a hole in the substrate material 104, as well as a partial trench 102′ in the substrate material 104 and a continuous trench 102″ in the substrate material 104.

FIG. 10 also illustrates the cross-sectional view of a pair of blind vias 106 and 108 according to some embodiments. As shown, FIG. 10 illustrates blind via 106 as a tapered bore hole from the top of substrate material 104, and blind via 108 as a tapered bore hole from the bottom of substrate material 104. Each of these blind vias may be formed as discussed above, and illustrated as a pair of disconnected tapered bore holes, each beginning at opposite surfaces of the substrate material 104 and extending to a termination point two-thirds of the way through the substrate material 104. Again, three separate top views of the pair of blind vias 106 and 108 are illustrated showing each as a pair of blind via holes 106 and 108 in the substrate material 104, a pair of partial trenches 106′ and 108′ in the substrate material 104, and a pair of continuous trenches 106″ and 108″ in the substrate material 104.

FIG. 10 also illustrates the cross-sectional view of a tapered through via 110, according to some embodiments. As shown, FIG. 10 illustrates tapered through via 110, formed as a tapered bore hole from the top and bottom of substrate material 104, and aligned in the middle so that the lower tapered bore hole of tapered through via 110 and the upper tapered bore hole of tapered through via 110 connect substantially in the middle of substrate material 104. Again, three separate top views of tapered through via 110 are illustrated showing tapered through via 110 as a hole in the substrate material 104, as well as a partial trench 110′ in the substrate material 104 and a continuous trench 110″ in the substrate material 104.

FIG. 10 also illustrates the cross-sectional view of a through via 112, according to some embodiments. As shown, FIG. 10 illustrates through via 112, formed as a bore hole from the top and bottom of substrate material 104, and aligned in the middle so that the lower bore hole of through via 112 and the upper bore hole of through via 112 connect substantially in the middle of substrate material 104. Again, three separate top views of through via 112 are illustrated showing through via 112 as a hole in the substrate material 104, as well as a partial trench 112′ in the substrate material 104 and a continuous trench 112″ in the substrate material 104.

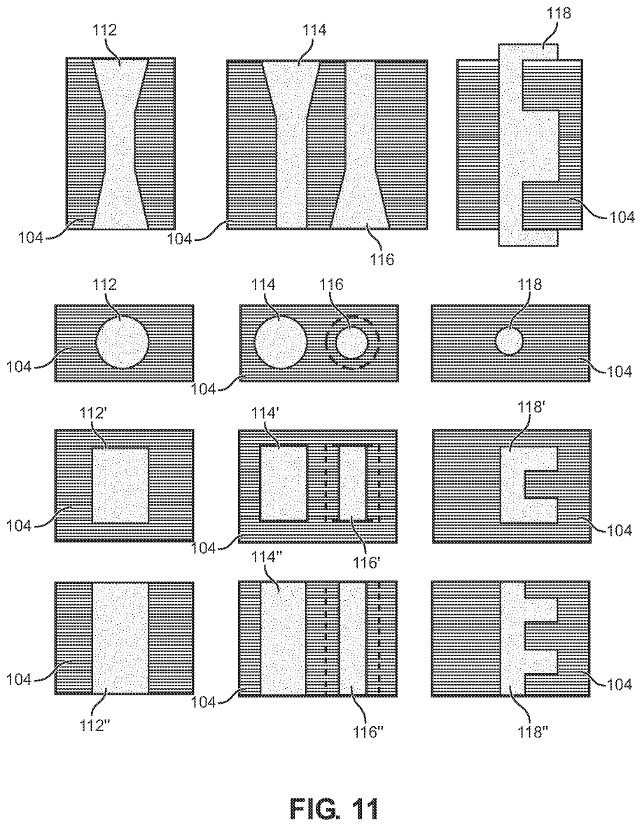

FIG. 11 illustrates, in diagrammatic form, multiple exemplary crack stop structures according to several of the embodiments. FIG. 11 illustrates the cross-section view of each of the exemplary crack stop structures along with the top view of each in three different forms: (i) a hole; (ii) a partial trench; and (iii) a continuous trench. As shown, FIG. 11 illustrates a single through via 112 as a crack stop structure according to some embodiments. Single through via 112 is created as a tapered bore hole, having a larger diameter at the top and a narrower diameter at its mid-point approximately one-half through the substrate material 104, and then tapering out to its egress point on the lower side of substrate material 104. Single through via 112 is then filled with materials as discussed above, i.e., insulator material, conductor material, or a combination of both. Three separate top views of single through via 112 are illustrated showing single through via 112 as a hole in the substrate material 104, as well as a partial trench 112′ in the substrate material 104 and a continuous trench 112″ in the substrate material 104.

FIG. 11 also illustrates the cross-sectional view of a pair of through vias 114 and 116 according to some embodiments. As shown, FIG. 11 illustrates through via 114 as a tapered bore hole from the top of substrate material 104, and through via 116 as a tapered bore hole from the bottom of substrate material 104. Each of these through vias may be formed as discussed above, and illustrated as a pair of disconnected tapered bore holes, each beginning at opposite surfaces of the substrate material 104 and extending to it egress point on the opposite side of the substrate material 104. Again, three separate top views of the pair of through vias 114 and 116 are illustrated showing each as a pair of through via holes 114 and 116 in the substrate material 104, a pair of partial trenches 114′ and 116′ in the substrate material 104, and a pair of continuous trenches 114″ and 116″ in the substrate material 104.

FIG. 11 also illustrates the cross-sectional view of an irregular 3-D through via 118 according to some embodiments. Three separate top views of the irregular 3-D through via 118 are illustrated showing each as an irregular 3-D through via 118 in the substrate material 104, a partial trench 118′ in the substrate material 104, and a continuous trench 118″ in the substrate material 104. Other structures are contemplated.

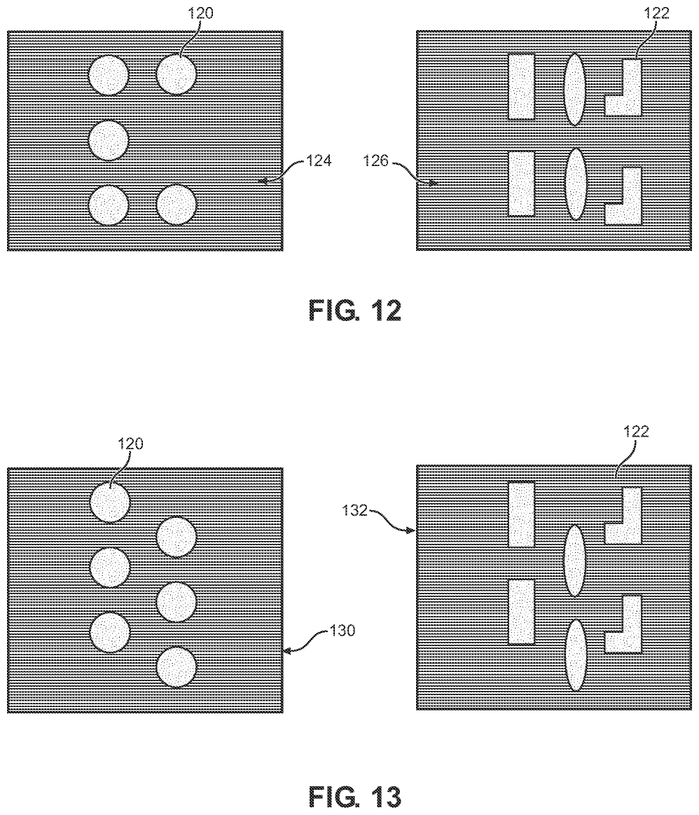

FIG. 12 illustrates, in diagrammatic form, an exemplary crack stop structure in a linearly arrayed combination of the through vias 120 in substrate material 124 as well as an exemplary crack stop structure in a linearly arrayed combination of the trenched vias and irregular 3-D through via 122 in substrate material 126, according to some embodiments. FIG. 13 illustrates, in diagrammatic form, an exemplary crack stop structure in a staggered array combination of the through vias 120 in substrate material 130 as well as an exemplary crack stop structure in a staggered array combination of the trenched vias and irregular 3-D through via 122 in substrate material 132, according to some embodiments. Arrays may be in a linear form 124,126, as illustrated in FIG. 12, or in staggered array form 130,132, as illustrated in FIG. 13. As discussed previously, more angles formed from 3D shape holes, partial trenches, continuous trenches, and irregular 3D structures are more desirable due to the dissipating characteristics of the various angles in the x- y- and z-planes.

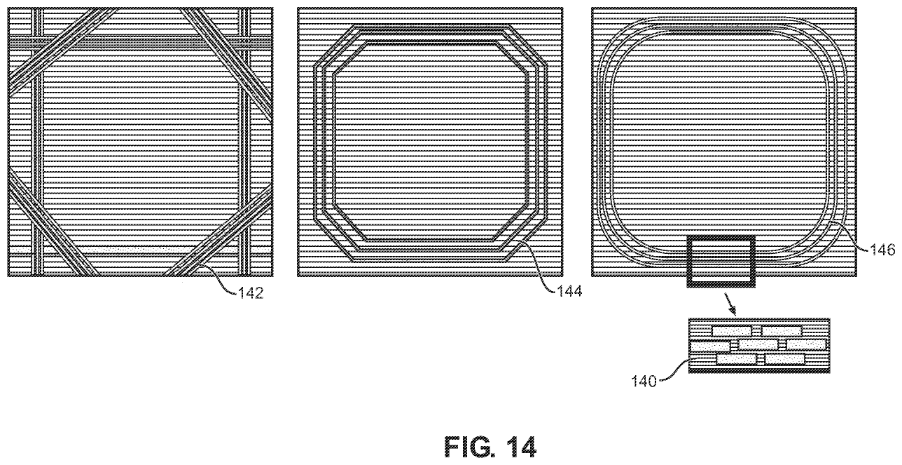

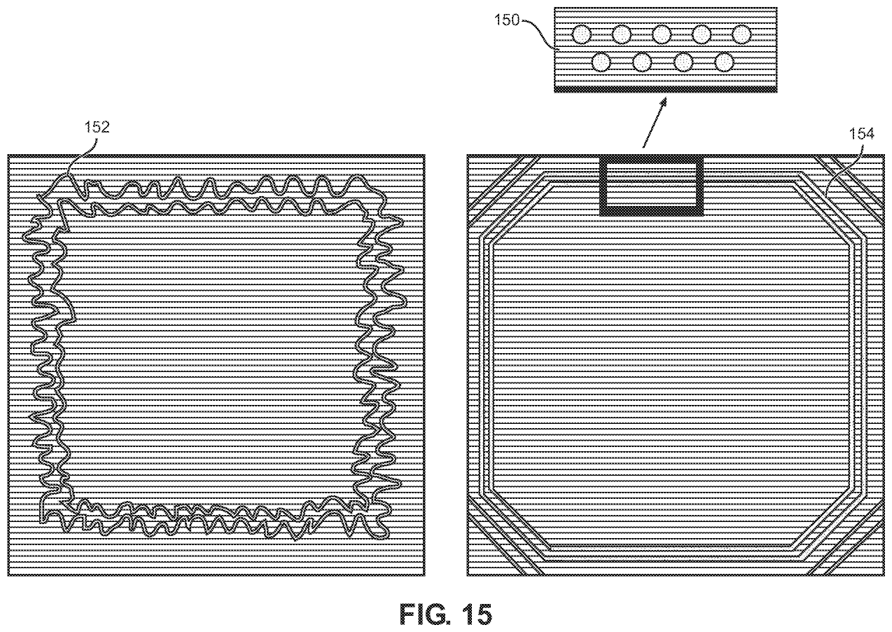

FIG. 14 illustrates, in diagrammatic form, crack stop patterns that may be utilized at both a panel level as well as at a unit level according to some embodiments. FIG. 15 illustrates, in diagrammatic form, additional crack stop patterns that may be utilized at both a panel level as well as at a unit level according to some embodiments. Arrays of the crack-stop structures 142, 144,146, 152, and 154 may be drawn at panel- and/or unit-level in a variety of seal ring patterns. Arrays of crack-stop structures 142, 144, 146, 152, and 154 may be drawn as staggered array of partial trenches 140 or as staggered array of through vias 150. The array patterns can be meandered as more meandering creates a better crack stop structure, as meandering angles tend to typically dissipate more energy.

Continuous crack-stop structures in a substrate core may be challenging to implement. Some structures may weaken the edge of the substrate core and create a predisposition for cracking due in part to the crack-stop structure itself. Multiple options for implementing a continuous crack-stop structure are available to address these challenges that may include utilizing: (i) partial continuous trench using any of the patterns of crack-stop structures disclosed herein or any other analogous pattern; (ii) localized continuous patterns with sparse/repeating arrays in other regions; and (iii) a reconstituted crack-stop wall within in the substrate core.

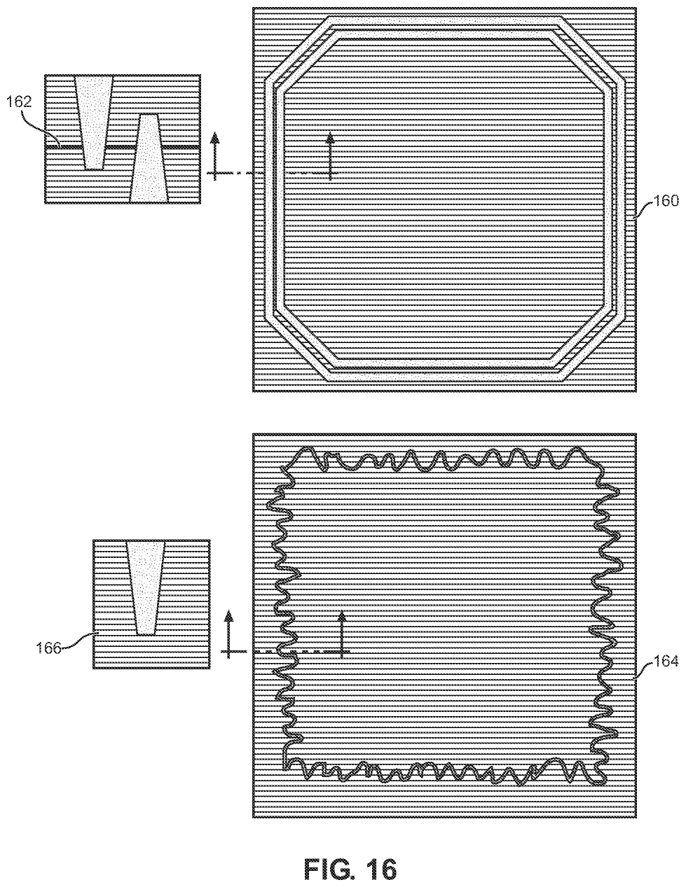

FIG. 16 illustrates in diagrammatic form exemplary partial continuous trench crack-stop structures according to some embodiments. These continuous trench structures 160 may be implemented using a pair of blind via 162, thus providing less stress on the edges of the substrate core. The meandering continuous trench structure 164 may be implemented using a single blind via 166 in a continuous form as described herein, and thus reducing the stress on the edges of the substrate core.

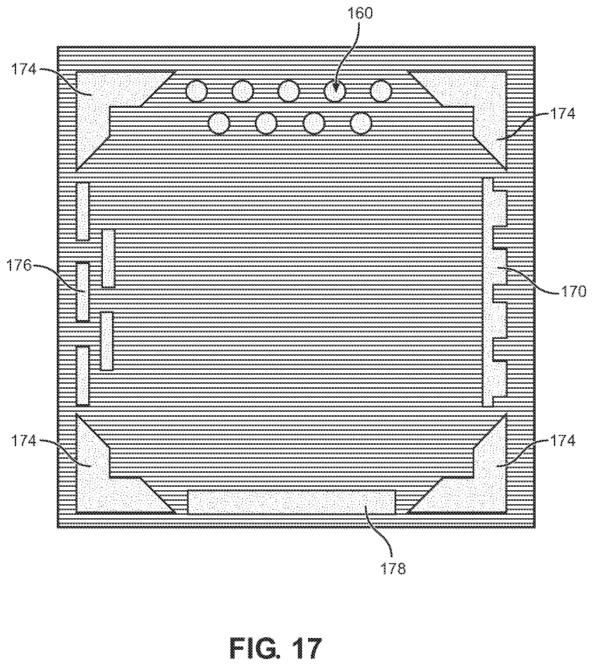

FIG. 17 illustrates, in diagrammatic form, another exemplary crack-stop structure according to some embodiments. FIG. 17 illustrates an exemplary of a localized continuous pattern with a sparse/repeating array in other regions. At the right side of the substrate core is an irregular trench crack stop structure 170. At the top of the substrate core is illustrated a sparse staggered array of tapered blind vias 172. The left side of the substrate core is a repeating array of trenched crack-stop structures 176. The bottom of the substrate core is lined with a continuous crack-stop structure 178. The corners of the substrate core are protected by continuous crack stop structures 174. Other embodiments analogous to those disclosed herein are anticipated.

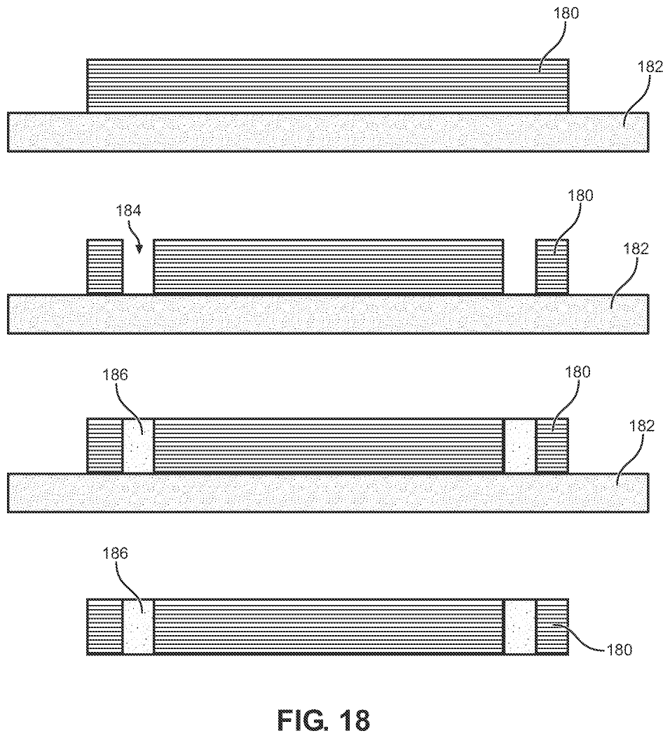

FIG. 18 illustrates in diagrammatic form an exemplary reconstituted crack-stop wall according to some embodiments. Reconstituted crack-stop wall is developed by a process of attaching the substrate core 180 to a temporary carrier 182. Next, a continuous trench 184 is formed all around the perimeter of substrate core 180. Continuous trench 184 is plugged with a metallic or insulative material 186, reconstituting the core into a single structure. Lastly, the temporary carrier 182 is released leaving behind the reconstituted substrate core 180 containing plug material 186t.

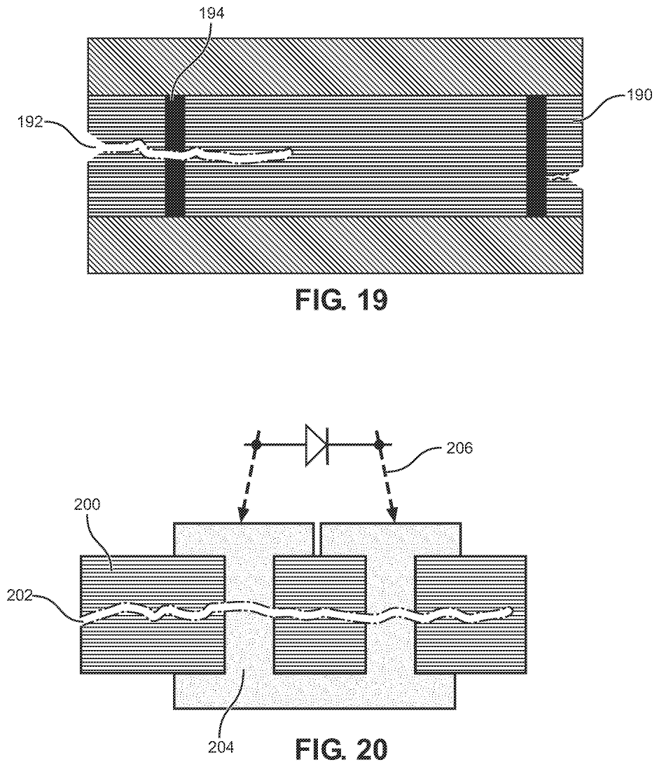

Not all cracks are defects that result in failure of the substrate. In many instanced, the cracks are stopped by a crack-stop structure similar to those disclosed herein. However, larger cracks may be of such magnitude or under such stress that the crack-stop structures fail to terminate the propagation of the crack in the substrate material. In these instances, what is needed is a detection mechanism sufficient to reveal the presence of a crack having broken though the crack-stop material and propagated further into the substrate. FIG. 19 illustrates, in diagrammatic form, an exemplary substrate core 190 with a crack-stop structure 194 having been placed therein. Crack 192, as illustrated, has propagated further into the substrate core 190 and has compromised the crack-stop structure 194 moving into the active area of the substrate core 190.

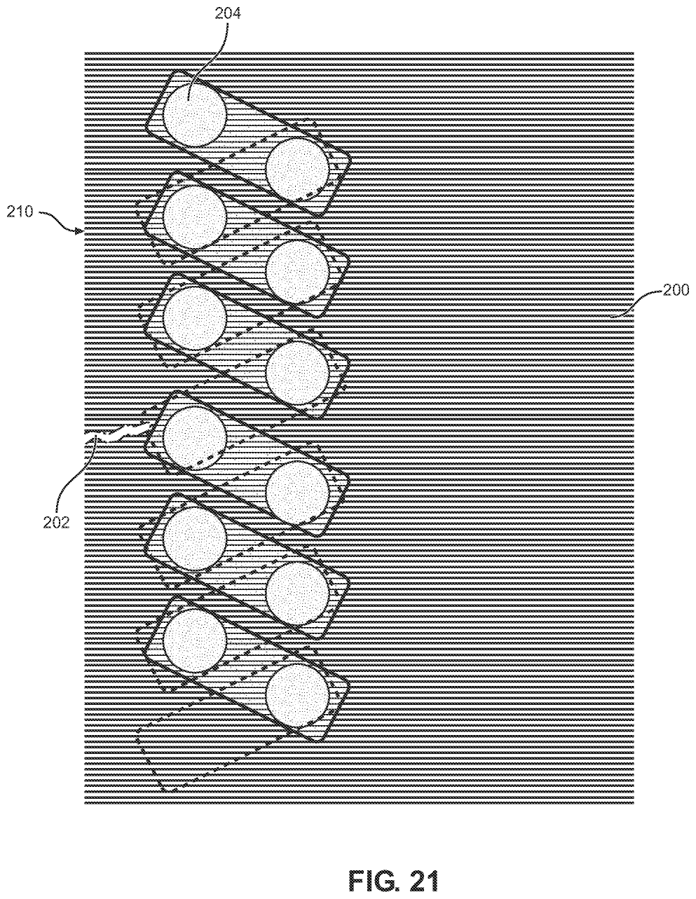

FIG. 20 illustrates a cross-sectional of a Z-plane crack-monitor structure that uses a daisy-chained crack-stop structure according to some embodiments. FIG. 21 illustrates, in diagrammatic form, a top view of a Z-plane crack-monitor structure that uses a daisy-chained crack-stop structure according to some embodiments. The crack-monitor structure could be tested for electrical continuity through procedures such as a standard diode-continuity test, resistance measurements, or electron beam tests. The Daisy-chained 210 crack stop can be connected to package RDL 206 to test the panel or unit for cracking in-line 202 during manufacturing after every build-up layer formation. The crack-monitor may or may not be part of the crack stop 204. These structures could be locally placed with or without crack-stops to detect substrate core 200 cracking 202.

In this specification, example embodiments have been presented in terms of a selected set of details. However, a person of ordinary skill in the art would understand that many other example embodiments may be practiced which include a different selected set of these details. It is intended that the following claims cover all possible example embodiments.

Thus, it will be apparent to one of ordinary skill that this disclosure provides for improved method and apparatus for use in semiconductor packaging substrates for crack cessation and detection in semiconductor packaging substrates.

Apparatus, methods and systems according to embodiments of the disclosure are described. Although specific embodiments are illustrated and described herein, it will be appreciated by those of ordinary skill in the art that any arrangement which is calculated to achieve the same purposes can be substituted for the specific embodiments shown. This application is intended to cover any adaptations or variations of the embodiments and disclosure. For example, although described in terminology and terms common to the field of art, exemplary embodiments, systems, methods and apparatus described herein, one of ordinary skill in the art will appreciate that implementations can be made for other fields of art, systems, apparatus or methods that provide the required functions. The invention should therefore not be limited by the above-described embodiment, method, and examples, but by all embodiments and methods within the scope and spirit of the invention.

In particular, one of ordinary skill in the art will readily appreciate that the names of the methods and apparatus are not intended to limit embodiments or the disclosure. Furthermore, additional methods, steps, and apparatus can be added to the components, functions can be rearranged among the components, and new components to correspond to future enhancements and physical devices used in embodiments can be introduced without departing from the scope of embodiments and the disclosure. One of skill in the art will readily recognize that embodiments are applicable to future systems, future apparatus, future methods, and different materials.

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope of the disclosure unless otherwise claimed. No language in the specification should be construed as indicating any non-claimed element as essential to the practice of the disclosure as used herein.

Terminology used in the present disclosure is intended to include all environments and alternate technologies that provide the same functionality described herein.

1. A semiconductor package substrate core comprising:
a substrate core material;
at least one crack cessation structure formed within said substrate core material, said crack cessation structure being formed in said substrate core material to a first depth; and
wherein said crack cessation structure comprises at least a selected one of one hole and one trench; said crack cessation structure being further characterized as being filled with a selected one of an insulative material and a metallic material.

2. The semiconductor package substrate core of claim 1 wherein said crack cessation structure formed in said substrate core material to a first depth is further characterized as being formed near the exterior edge of said package substrate.

3. The semiconductor package substrate core of claim 2 wherein said first depth is greater than one-half of the thickness of said package substrate.

4. The semiconductor package substrate core of claim 1, wherein the at least one hole is characterized as a blind via.

5. The semiconductor package substrate core of claim 1, wherein the at least one hole is characterized as a through hole.

6. The semiconductor package substrate core of claim 1, wherein the at least one hole is characterized as an offset pair of blind vias.

7. The semiconductor package substrate core of claim 1, wherein the at least one trench is further characterized as a partial trench.

8. A method for manufacturing a semiconductor package substrate core, comprising:
forming a substrate core material;
forming at least one crack cessation structure in said substrate core material, said crack cessation structure being formed in said substrate core material to a first depth, said crack cessation structure comprising at least a selected one of one hole and one trench; and
filling the at least a selected one of one hole and one trench with a selected one of an insulative material and a metallic material.

9. The method of manufacturing a semiconductor package substrate core of claim 8 wherein said crack cessation structure formed in said substrate core material to a first depth is further characterized as being formed near the exterior edge of said package substrate.

10. The method of manufacturing a semiconductor package substrate core of claim 9 wherein said first depth is greater than one-half of the thickness of said package substrate.

11. The method of manufacturing a semiconductor package substrate core of claim 8, wherein the at least one hole is characterized as a blind via.

12. The method of manufacturing a semiconductor package substrate core of claim 8, wherein the at least one hole is characterized as a through hole.

13. The method of manufacturing a semiconductor package substrate core of claim 8, wherein the at least one hole is characterized as an offset pair of blind vias.

14. The method of manufacturing a semiconductor package substrate core of claim 8, wherein the at least one trench is further characterized as a partial trench.

15. A semiconductor package substrate core comprising:
a substrate core material; and
at least one crack cessation structure formed within said substrate core material, said crack cessation structure further comprising:
a first hole formed in said substrate core material to a first depth, said hole being formed in a first surface of said substrate core material, and said hole being filled with a selected one of an insulative material and a metallic material; and
a second hold formed in said substrate core material to a second depth, said hole being formed in a second surface of said substrate core material opposite said first surface, and said hole being filled with a selected one of an insulative material and a metallic material.

16. The semiconductor package substrate core of claim 15 wherein said crack cessation structure formed in said substrate core material is further characterized as being formed near the exterior edge of said package substrate.

17. The semiconductor package substrate core of claim 16 wherein said first depth is greater than one-half of the thickness of said semiconductor package substrate core, and said second depth is greater than one-half of the thickness of said semiconductor package substrate core.

18. An apparatus comprising:
a substrate;
a first defect sensor structure comprising;
a first plated-through hole disposed in said substrate having:
a first top terminal disposed on a first surface of said substrate; and
a first bottom terminal disposed on a second surface of said substrate;
a second plated-through hole disposed in said substrate having:
a top terminal disposed on said first surface of said substrate; and
a second bottom terminal disposed on said second surface of said substrate; and
a conductive connecting track coupled to said first bottom terminal and to said second bottom terminal; and
said first defect sensor structure configured to receive a detection signal therethrough between the first top terminal and the second top terminal to detect a break in the conductive track between said first and second top terminals and thereby detect a defect in the substrate.
